(19) United States
(12) Patent Application Publication
(10) Pub. No.: US 2017/0307664 A1
(43) Pub. Date: Oct. 26, 2017

(54) SENSORS, SYSTEMS AND METHODS FOR RESIDUAL CURRENT DETECTION

(71) Applicant: Infineon Technologies AG, Neubiberg (DE)

(72) Inventor: Udo Ausserlechner, Villach (AT)

(21) Appl. No.: 15/648,050

(22) Filed: Jul. 12, 2017

Related U.S. Application Data
(62) Division of application No. 13/832,300, filed on Mar. 15, 2013.

(51) Int. Cl. G01R 15/20

(52) U.S. Cl. CPC G01R 15/20; G01R 15/207; G01R 15/202; G01R 15/205

(57) ABSTRACT

Embodiments relate to sensor systems and methods for detecting residual currents. In embodiments, a sensor comprises a magnetic core and a plurality of conductors passing through an aperture of the core. The magnetic core comprises a gap in the core itself, and a magnetic field sensor is arranged proximate to but not within this gap, in contrast with conventional approaches, in order to detect a net flux in the core. Advantageously, embodiments can be used in applications in which it is desired to detect AC or DC currents.

### TECHNICAL FIELD

The invention relates generally to sensors and more particularly to sensors, such as magnetic field sensors, for detecting residual currents.

### BACKGROUND

Detection of residual currents is important to prevent wasted electricity in addition to more serious events such as electrocutions, electrical fires and equipment damage. Conventional residual current sensors can comprise a coil wound around a soft magnetic core, with two conductors running through an aperture of the core. If a sum of the currents in the conductors is not equal to zero, in other words if the current is not balanced between the two conductors, a net magnetic flux is present in the core. This can signal a leakage of current to ground, another circuit or some other point. Transients of the net flux in the core can lead to an induced electromotive force (EMF) in the coil, which can be detected by a circuit such that power can be cut off or other action taken to stop the current from flowing.

These conventional residual current sensors suffer from some drawbacks, however. First, they typically work only for transient or AC currents. Therefore, they are not applicable so applications in which it is also desired to detect DC currents. Second, they generally need a coil, which is expensive to manufacture. Furthermore, if that coil saturates, the sensor can suffer from limited sensitivity and accuracy. This can be particularly important because the currents which are desired to be detected are often very small, for example a leakage of about 0.1 A in a 100 A system.

### SUMMARY

Embodiments relate to residual current sensing systems and methods. In an embodiment, a residual current sensing system comprises a magnetic core comprising a gap, the gap having a width defined by opposing edges of the magnetic core such that the magnetic core is noncontiguous around a center aperture; a plurality of current conductors disposed within the center aperture; a sensor package having a first dimension greater than the width of the gap and arranged outside of and proximate to the gap such that the width and the first dimension are coaxial and the sensor package extends across the gap; and at least one sensor element disposed in the sensor package and configured to sense a magnetic field induced in the magnetic core when current flows in at least one of the plurality of conductors.

In another embodiment, a method of detecting a residual current comprises providing a residual current sensing system comprising a magnetic core comprising a gap therein and a sensor package arranged adjacent to and across the gap; and sensing, by at least one sensor element disposed in the sensor package, a current induced in the magnetic core by current flow in at least one conductor arranged in the magnetic core.

In an embodiment, a residual current sensing system comprises a magnetic core comprising a first portion and a second portion defining a gap, the gap having a width defined by opposing edges of the magnetic core such that the magnetic core is noncontiguous around a center aperture; a plurality of current conductors disposed within the center aperture; a sensor package having a first dimension greater than the width of the gap and comprising a first portion arranged outside of and proximate to the gap such that the width and the first dimension are coaxial and the sensor package extends across the gap, the sensor package further comprising a second portion arranged at least partially within the gap; and at least one magnetic field sensor element disposed in the second portion of the sensor package and configured to sense a magnetic field induced in the magnetic core when current flows in at least one of the plurality of conductors.

### BRIEF DESCRIPTION OF THE DRAWINGS

The invention may be more completely understood in consideration of the following detailed description of various embodiments of the invention in connection with the accompanying drawings, in which:

FIG. 1 is a side cross-sectional view of a residual current sensor system according to an embodiment.

FIG. 2 is a side cross-sectional view of a residual current sensor system having an alternate relative positioning of a sensor package and a magnetic core according to an embodiment.

FIG. 3A is a side cross-sectional view of a residual current sensor system having another relative positioning of a sensor package and a magnetic core according to an embodiment.

FIG. 3B is a side cross-sectional view of a residual current sensor system including a soft magnetic layer according to an embodiment.

FIG. 3C is a side cross-sectional view of a residual current sensor system comprising a sleeve and having another relative positioning of a sensor package and a magnetic core according to an embodiment.

FIG. 3D is a side cross-sectional view of a residual current sensor system comprising a two-piece sleeve according to an embodiment.

FIG. 4 is a side cross-sectional view of a residual current sensor system comprising a two-piece magnetic core according to an embodiment.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

Embodiments relate to sensor systems and methods for detecting residual currents. In embodiments, a sensor comprises a magnetic core and a plurality of conductors passing through an aperture of the core. The magnetic core comprises a gap in the core itself, and a magnetic field sensor is arranged proximate to but not within this gap, in contrast with conventional approaches, in order to detect a net flux in the core. Advantageously, embodiments can be used in applications in which it is desired to detect AC or DC currents.

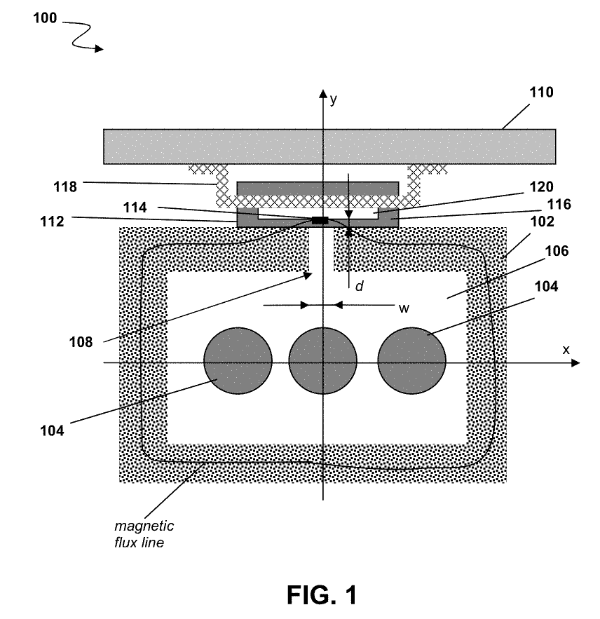

Referring to FIG. 1, a residual current sensor system 100 is depicted. Sensor system 100 comprises a magnetic core 102 and a plurality of current conductors 104 which pass through a center aperture 106 in core 102. In embodiments, conductors 104 comprise copper, for example copper wires, punched copper sheet metal or copper traces in or on a printed circuit board in various embodiments. Conductors 104 are advantageously arranged symmetrically with respect to the y-axis in FIG. 1, with a particular position defined at least in part by a geometry of core 102. In embodiments, conductors 104 can be insulated, for example by printed circuit boards or another dielectric, non-conducting material, though insulation is not depicted in FIG. 1.

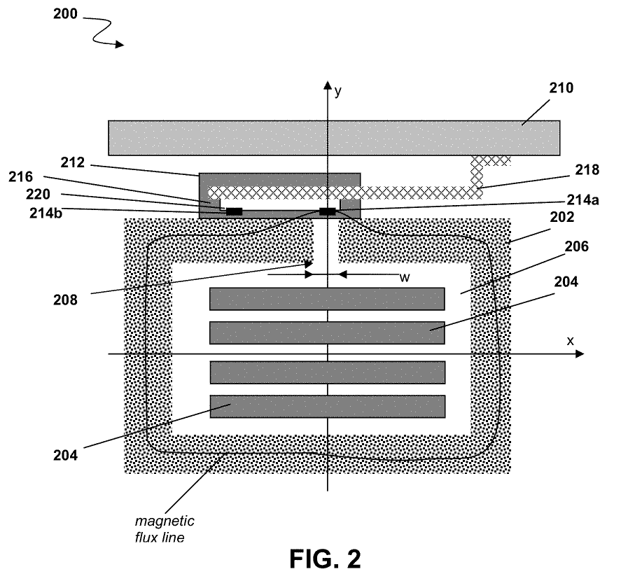

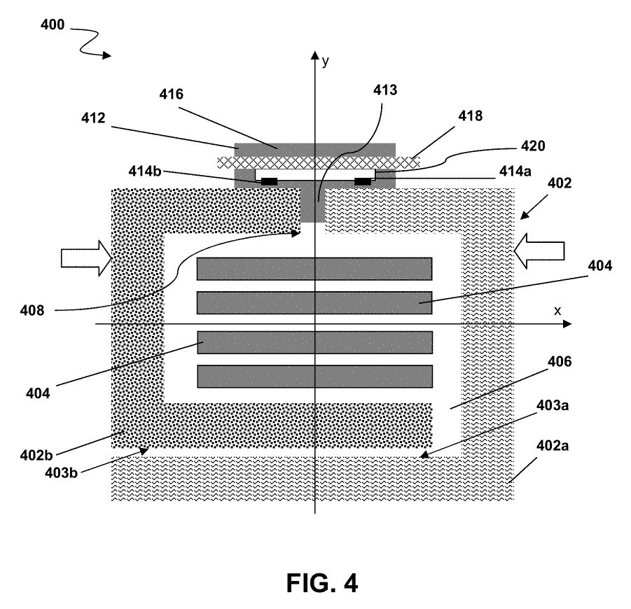

Core 102 also comprises a gap 108 defined by opposing edges of core 102 such that core 102 is noncontiguous around center aperture 106. In one embodiment, core 102 can a comprise single-piece construction and/or a material such permalloy, Mumetal, ferrite or another material having a low coercivity, though other materials can be used in other embodiments. In another embodiment discussed in more detail with respect to FIG. 4 below, core 102 can comprise at least two pieces, such as two halves, which are clamped, fixed, or otherwise combined and with gap 108 defined therebetween. A printed circuit board (PCB) 110 or other structure is arranged proximate core 102 such that a magnetic field sensor package 112 can be mounted proximate or to core 102, in particular with a magnetic field sensor 114 in or on package 112 arranged proximate or adjacent to gap 108. In embodiments, sensor package 112 has a dimension, such as the width x-dimension in FIG. 1, that is coaxial with a width x-dimension of gap 108, and the dimension of package 112 is greater than the width such that package 112 extends across the entire width of gap 108. Package 112 can be centered with respect to a central y-axis of gap 108, as in FIG. 1, or package 112 can be off-center (see, e.g., FIG. 2). In general, however, a portion of package 112 comprising sensor 114 is arranged outside of gap 108, such that sensor 114 is also arranged outside of gap 108. Embodiments in which other portions of package 112 are arranged at least partially in gap 108 are discussed in more detail below with reference to FIG. 4.

In embodiments, magnetic field sensor 114 comprises a Hall effect sensor element or device, such as a vertical Hall effect sensor element or device; a magnetoresistive (xMR) element or device, such as an AMR, GMR, TMR, CMR or other xMR element or device; a giant magneto-impedance device; or another suitable magnetic field sensing element or device. A particular orientation and configuration of sensor element 114, in this and other embodiments, can vary according the type of magnetic field sensor device implemented. For example, as depicted in FIG. 1, magnetic field sensor 114 comprises a vertical Hall effect sensor device or an xMR sensor device. In other embodiments, sensor 114 can be rotated or the position other altered such that an ordinary Hall effect sensor can be used. This is but one example, and other sensors and configurations can be used in other embodiments as appreciated by those skilled in the art.

In general, however, the position of sensor 114 with respect to core 102, in particular gap 108, is a significant factor, as sensor 114 is to sense a flux in core 102, a path of which is affected by gap 108. Stray flux, or fluxlines which leave or extend out of core 102 and around the area of gap 108, can depend on the width of gap 108 as well as other characteristics of the geometry of gap 108. For example, the opposing edges of core 102 which define gap 108 can be parallel or non-parallel, stepped, curved or comprise some other non-planar surface, and can have these characteristics in any direction of the edges or surfaces, in various embodiments.

Thus, in embodiments, sensor 114 is positioned as close as possible to but not within gap 108, such as with d being less than about 0.5 mm in embodiments, for example about 0.3 mm in one embodiment. In embodiments, d can be defined by a thickness of a mold compound 116 within package 112, and/or by insulation layer(s) of package 112 and/or core 102. For example, in embodiments core 102 can be partially or fully wrapped in an insulation foil, or a platelet can be inserted between core 102 and package 112.

Package 112 comprises a surface-mount device (SMD) in embodiments and is coupled to PCB 110 by a leadframe 118, to which a die 120, such as a semiconductor die, is coupled. Package 112 can comprise some other suitable configuration in other embodiments, such as a leadless package like a very thin quad-flat no-lead (VQFN) package. Magnetic field sensor 114 is arranged on die 118, and mold compound 116 generally surrounds magnetic field sensor 114 in an embodiment.

In embodiments, core 102 comprises a soft magnetic material, such as a “soft” iron or other suitable material, and is generally toroidal in shape with a rectangular or round cross-section and/or aperture, with at least a portion of the surface of core 102 to which package 112 is coupled is flat. In other embodiments, core 102 can have some other shape, and/or the surface at which package 112 is coupled is only partially flat or some other configuration which enables package 112 to be coupled with magnetic field sensor 114 arranged with respect to gap 108. Package 112, more generally the assembly of PCB 110, can be coupled to core 102 in embodiments by an adhesive, a mechanical bond or attachment, or some other suitable material or process in embodiments.

An example magnetic flux line is included in FIG. 1. With magnetic field sensor 114 arranged proximate to and outside of gap 108, such as at a distance of about 0.3 mm in an embodiment, sensor 114 falls within the stray field of core 102 which is diverted out of core 102 by gap 108. In general, d can be scaled with w, for example according to w/3<d<3*w in embodiments. The distance also can vary if insulation is used between core 102 and package 112, as insulation can be about 0.2 mm to about 1.5 mm thick in embodiments. The stray field is slightly weaker but nevertheless sufficient for stray current detection purposes. Because a narrower gap 108 increases the strength of this stray field, in embodiments the width of gap 108 is less than about 1 mm in embodiments, such as about 0.5 mm to about 0.7 mm in embodiments, or about 0.6 mm in one embodiment, though gap can also be wider, such as up to about 5 mm in embodiments. Arranged as depicted in FIG. 1, which includes an x-y grid for reference, magnetic field sensor 114 is arranged on the symmetry axis of core 102 such that sensor 114 is sensitive to the horizontal x-component of the magnetic field, or Bₓ, induced by core 102. In practice, assembly tolerances can cause sensor 114 to be positioned off of the symmetry axis, such that in embodiments system 100 can comprise a plurality of sensors 114 on die 120. The plurality of sensors 114 could be arranged on die 120 spaced apart from one another, e.g., by about 100 μm in an embodiment, in a grid configuration, such that the particular sensor 114 being closest to the ideal symmetry axis position after assembly, e.g., x=0 as in FIG. 1, is selected for use in the field. The other sensors 114 could be disabled, for example following manufacturing end-of-line testing in which the best-positioned sensor 114 is identified and stored in a memory on die 120 or in, e.g., an EEPROM device on PCB 110.

Positioning magnetic field sensor 114 near but outside of gap 108 provides several advantages over conventional, sensor-in-gap approaches. First, system 100 is easier to manufacture than sensor-in-gap systems, as it is easier to arrange sensor 114 proximate to rather than within gap 108, as appreciated by those skilled in the art. This also can provide a cost savings. Second, system 100 can be more sensitive than sensor-in-gap systems, for example because gap 108 can be made narrower which increases the magnetic field, enabling smaller residual currents to be detected. Additionally, sensor-in-gap systems require a wider gap in order to accommodate a sensor therewithin. Therefore, a reduction in space or area requirements can be realized by arranging the sensor outside of the gap as in FIG. 1.

Additional configurations are also possible, which can provide additional advantages in embodiments. Herein throughout, the same or similar reference numerals (e.g., core 102 in FIG. 1 and core 202 in FIG. 2, for example) will be used to refer to the same or similar features or elements in the drawings, unless otherwise specified.

Referring to FIG. 2, another sensor system 200 is depicted which comprises two magnetic field sensor elements 214a and 214b which can be used in a differential and/or gradiometric sensing system. Other embodiments discussed herein also can be used as differential and/or gradiometric sensors and systems configured to sense a difference in and/or a spatial gradient of a magnetic field. A first sensor element 214a is arranged similar to that of sensor 114 in FIG. 1, on symmetry axis of core 202, i.e., at x=0 as depicted in FIG. 2. The second sensor element 214b is shifted as far as die 220 will allow in one or the other of the x-directions, i.e., in the negative x-direction in FIG. 2. For example, sensor element 214b can be arranged at x=−2 mm in an embodiment, though this distance can vary in other embodiments. So arranged, sensor element 214a will sense a stronger Bₓ field while sensor element 214b will sense a weaker Bₓ field. In embodiments, sensor elements 214a and 214b comprise vertical Hall effect sensor elements, or some other magnetic field sensor elements suitable arranged. In other embodiments, sensor elements 214a and 214b can comprise xMR sensor elements arranged in a Wheatstone bridge configuration. Thus, the bridge configuration can be arranged such that one element of the bridge is positioned at x=0 and another is positioned at x=−2 mm or some other suitable point.

A difference in the fields sensed by sensor elements 214a and 214b then can be determined, such that system 200 comprises a differential sensing system. An advantage of differential sensing systems can be improved accuracy because common errors affecting both or all sensor elements, e.g., zero-point, offset, interference and disturbance magnetic fields and other errors, can be canceled in the combined differential signal.

Instead of an SMD package as in FIG. 1, package 212 comprises leads 218 in an embodiment, such that package 212 can be glued, adhered or otherwise affixed to core 202 more closely. Leads 218 can be sized and configured to be sufficiently flexible in embodiments so as to absorb movement between PCB 210 and core 202, thereby keeping the arrangement of sensor elements 214a and 214b, surrounded by mold compound 216 in package 212, consistent with respect to core 202 and gap 208. In other embodiments, the SMD package configuration of system 100 of FIG. 1 can be implemented as part of system 200 of FIG. 2, and vice-versa. The same is true for other elements and features discussed with respect to any particular embodiment herein, which generally can be implemented in other embodiments as appreciated by those skilled in the art.

System 200 also comprises an alternate configuration of conductors 203. In system 200, conductors 204 comprise bars which are elongated along the x-axis, in contrast with the round, wire-like structure of conductors 104 in FIG. 1. Conductors 204 also are mirror-symmetric with respect to the y-axis. This symmetry can reduce or prevent errors in the net flux distribution around sensor elements 214a and 214b related to inaccurate positioning of conductors 204 with respect to the x-axis and therefore gap 208. In embodiments, conductors 204 are stacked in the y-direction while conductors 104 are stacked in the x-direction. In other embodiments, conductors 104 and/or conductors 204 can be interleaved in any number of different ways, with different ones of the conductors coupled in series and/or parallel, or all of the conductors 204 and/or 104 can be connected in series with one another, which can provide a greater sensitivity. Again, as previously mentioned, elements and features of one embodiment can be implemented in other embodiments, such that conductors 104 could be implemented in system 200 in an embodiment, and conductors 204 could be implemented in FIG. 1, for example.

In other embodiments, sensor system 200 can comprise more than two sensor elements 214a and 214b. For example, in one embodiment sensor system 200 comprises three sensor elements for a second-order gradiometer, each sensitive to the Bₓ magnetic field component (such as if arranged similarly to system 200 of FIG. 2) or another magnetic field component if arranged in another way or on another axis. For purposes of discussing this example, a configuration similar to that of system 200 in FIG. 2 will be used, though comprising three sensor elements. A first sensor element, Bx1, is arranged at x=0, and the other two sensor elements are arranged on opposing sides of the first sensor element, equidistantly spaced therefrom, e.g., with Bx2 at x=1 mm and Bx3 at x=−1 mm, though these dimensions can vary. Then, the sensor system can use the signals from all three sensor elements to calculate an overall signal, for example 2*Bx1−Bx2−Bx3. Such a system can be even more robust with respect to external disturbances in embodiments.

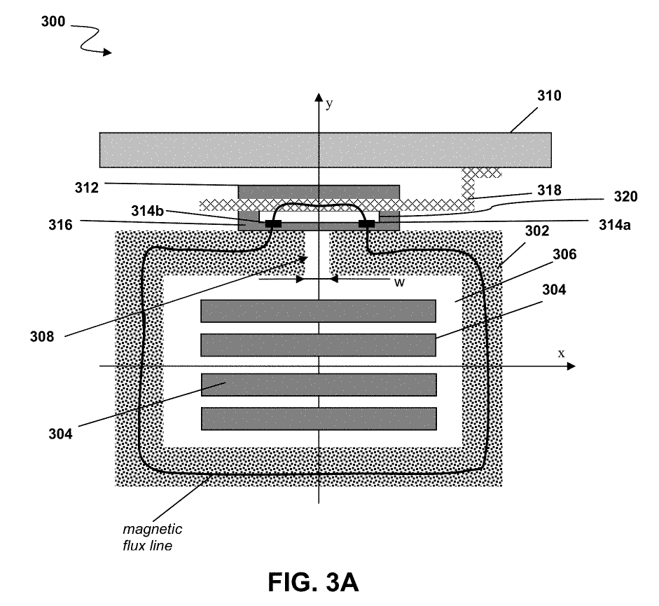

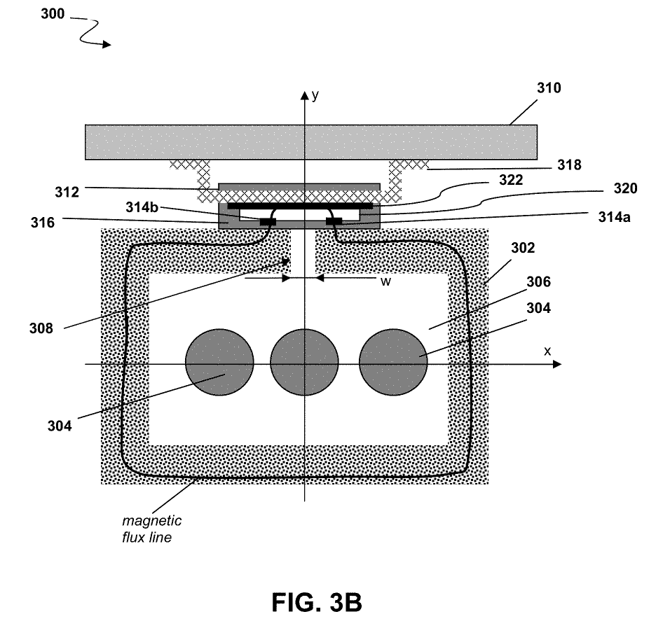

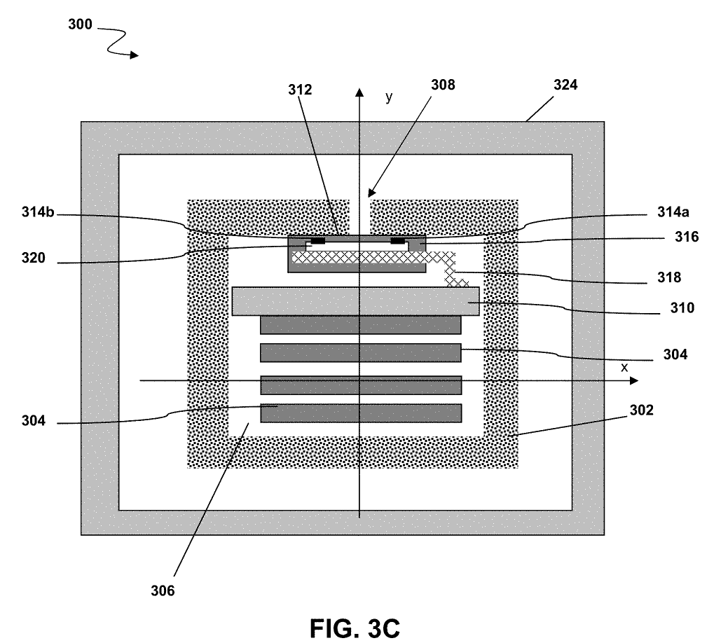

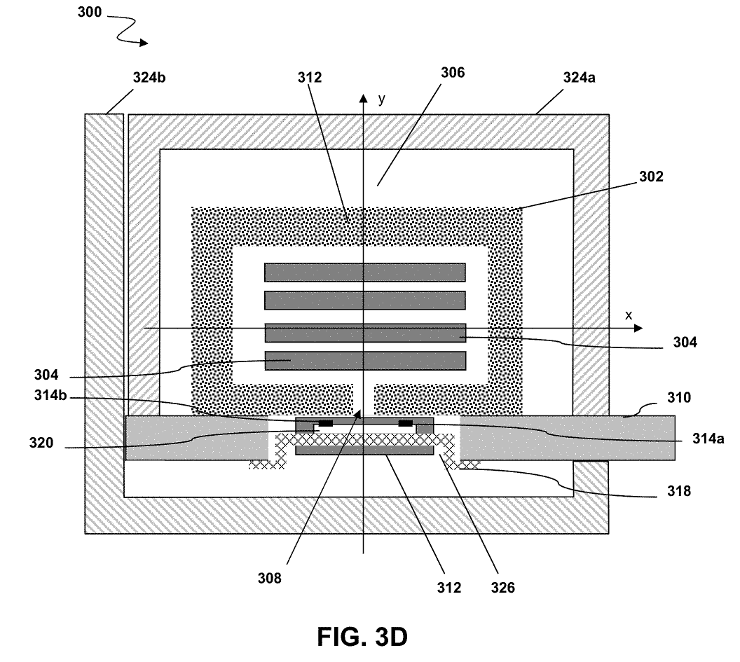

As previously mentioned, ordinary Hall effect sensor elements, or Hall plates, can be used in embodiments, instead of vertical Hall effect or xMR devices, for example. Referring to FIG. 3A, in embodiments in which sensor elements 314a and 314b comprise Hall plates, sensor elements 314a and 314b are sensitive to the B_{y} magnetic field component and therefore are arranged symmetrically with respect to the y-axis. For example, sensor elements 314a and 314b can be spaced apart in one embodiment by about 0.8 mm, such that sensor element 314a is positioned at x=0.4 mm and sensor element 314b is positioned at x=−0.4 mm, those these dimensions can vary in other embodiments. In general, however, sensor elements 314a and 314b will be spaced apart by a distance that is at the same as or greater than the width w of gap 302.

In operation, system 300 can determine a difference between the two sensor signals, for example By1−By2, wherein By1 is the signal from sensor element 314a and By2 is the signal from sensor element 314b. In embodiments, such as the one of FIG. 3A in which the width w of gap 308 is less than about 1 mm, such as about 0.5 mm to about 0.7 mm, By1−By2 is about 1 μT (micro-Tesla) for a residual current of about 1 mA. Therefore, residual currents of about 20 mA to about 30 mA can be easily detectable in embodiments.

Core 302, conductors 304, aperture 306, PCB 310, package 312, mold compound 316, leads 318 and die 320 can be similar to similar elements discussed herein with respect to other figures and embodiments. As previously mentioned, elements from one embodiment discussed and/or depicted herein can be used in combination with elements from other embodiments, even though specific combinations may not be discussed or depicted here.

FIG. 3B is similar to FIG. 3A, though in FIG. 3B system 300 further comprises a soft magnetic layer 322, such as a soft iron material, provided on a first surface of die 320 such that die 320 is arranged between layer 322 and core 302. Sensor elements 314a and 314b can be arranged as in FIG. 3A, as depicted, or according to some other configuration in other embodiments. Die 320 is kept thin in embodiments to minimize a distance between layer 322 and sensor elements 314a and 314b, such as less than about 200 μm in embodiments, for example less than about 100 μm in some embodiments, and less than about 50 μm in some embodiments. Moreover, layer 322 can be wider than the spacing of sensor elements 314a and 314b in embodiments, such as even wider than die 320. This can reduce adverse effects on sensitivity with respect to residual current and/or robustness against background fields that can be related to positioning tolerances of die 320 with respect to layer 322. Layer 322 can help to insulate sensor elements 314a and 314b from background magnetic disturbances and also make system 300 less prone to assembly tolerances. For example, in operation a magnetic field caused by currents in conductors 304 affecting sensor element 314a is directed downward with respect to the orientation on the page, while a magnetic field affecting sensor element 314b is directed upward. Subtracting the vertical B_{y} fields, for example when sensor elements 314a and 314b comprise Hall plate sensor devices, provides an effective doubling of the signal, given that the signals are of opposite signs. Conversely, external disturbance fields can be substantially homogeneous and therefore can have the same sign or direction affecting sensor elements 314a and 314b, which therefore cancel one another.

Referring to FIG. 3C, in another embodiment the effects of external magnetic fields can be reduced by providing a shielding magnetic sleeve 324 around or enclosing core 302. In embodiments, sleeve 324 comprises a soft magnetic material, for example the same or a similar material to that of core 302. In one embodiment, sleeve 324 comprises soft magnetic steel, while core 302 comprises a higher quality and/or higher performance material such as permalloy, Mumetal, ferrite or another material having a low coercivity, or some other suitable material in embodiments. These materials can be used in other embodiments as well, including for magnetic layer 322 in FIG. 3B.

As depicted, sleeve 324 partially or fully surrounds core 302 and sensor package 312. In embodiments, a sufficient separation between an outer surface of core 302 and an inner surface of sleeve 324 must exist to avoid sleeve 324 shorting or other affecting the flux in core 302. A minimum separation distance along an entire perimeter of core 302 can be selected such that the equivalent magnetic resistance between core 302 and sleeve 324 is greater than an equivalent magnetic resistance of gap 308. Thus, if gap 308 is about 0.5 mm wide and has a cross-sectional area of about 10 mm² in an embodiment, and if a perimeter surface of core 302 is about 300 mm², then a distance between core 302 and sleeve 324 should be larger than about 15 mm (0.5*10/300) in an embodiment. For example, in embodiments sleeve 324 and core 302 are separated by at least about 5 mm, for example about 15 mm. Core 302 itself can have a cross-sectional thickness into the drawing plane of FIG. 3B in a range of about 5 mm to about 15 mm in embodiments, while sleeve 324 can have a cross-sectional thickness, also into the drawing plane, in a range of about 10 mm to about 25 mm in embodiments. A material which sleeve 324 comprises, such as a sheet metal in an embodiment, can be in a range of about 0.5 mm to about 1.5 mm thick in embodiments. These dimensions, such as for core 302, can apply to other embodiments as well.

In embodiments, sensor package 312 is arranged within aperture 306 of core 302, i.e., core 302 is positioned between package 312 and sleeve 324. Though manufacturing such a configuration can be more complex than for other embodiments, an advantage can be that core 302 can protect package 312 when package 312 is arranged therewithin. The relative positions of package 312 and gap 308, however, are similar, with sensor elements 314a and 314b spaced apart from one another on die 320, on opposing sides of gap 308 along the x-axis. Package 312 is also coupled to PCB 310 by one or more leads 318, with PCB 310 and leads 318 also arranged within aperture 306 of core 302. PCB 310 is arranged proximate or coupled to one of the conductors 304 in embodiments, which can be the same as or similar to conductors discussed with respect to other embodiments and figures. Positioned as such, sensor elements 314a and 314b are spaced further apart from conductors 304 than in other embodiments, which can be advantageous with respect to reducing the effect of conductor arrangement tolerances on the magnetic field sensed by sensor elements 314a and 314b.

In yet another embodiment, sleeve 324 can comprise at least two portions 324a and 324b, such as is depicted in FIG. 3D, and PCB 310 can support sleeve 324 as well as core 302 and package 312. PCB 310 can comprise an aperture 326, in which package 312 can be arranged, such as before soldering components to PCB 310. Thus, PCB 310 can be reversed from a typical configuration and be arranged top-side down, such that traces and other interconnects are arranged on the lower surface, e.g., to which leads 318 can be soldered as depicted in FIG. 3D. In this embodiment, sensor package 312 can be coupled to core 302 or separated therefrom, such as by about 0.5 mm or less, such as by about 0.1 mm, given the mounting configuration with PCB 310. Sleeve 324 comprises two portions 324a and 324b as depicted in FIG. 3D. It can be advantageous to arrange one of the portions, here portion 324b, at an edge of PCB 310, to provide a contiguous surface along at least one side. Other configurations, including with respect to one or more relative positions of sleeve portions 324a and 324b, PCB 310, package 312 and/or core 302, can be implemented in other embodiments.

As previously mentioned, the soft magnetic core can comprise a “split core” configuration in embodiments. For example, at least two core portions, such as two halves or other pieces being differently or equally sized and configured, can be clamped, fixed, or otherwise combined, which can help to keep dimensions of gap 108 consistent. Referring to system 400 of FIG. 4, core 402 comprises two such core portions 402a and 402b. Core portions 402a and 402b are differently sized, such that core portion 402a has a larger vertical cross-sectional dimension, as well as a larger horizontal cross-sectional dimension at least along one surface. Core portions 402a and 402b are somewhat interleaved or overlapping in that an outer bottom surface 403b of portion 402b opposes at least a partial length of an upper bottom surface 403a of portion 402a. In embodiments, a minimum separation in the y-direction and a maximum length in the x-direction (as identified in FIG. 4) between surfaces 403a and 403b are advantageous to minimize net effects of the separation between those surfaces 403a and 403b of portions 402a and 402b. Ends of core portions 402a and 402b also oppose each other across or to form gap 408. Other configurations can be used in other embodiments, such that portions 402a and 402b can be reversed or rotated, or other shapes and relative layouts implemented. For example, core portions 402a and 402b can be mounted as for sleeve portions 324a and 324b in FIG. 3D, such that at least one portion is mounted to a side or end of PCB 310. In embodiments, core portions 402a and 402b comprise the same material, such as a soft magnetic material, though in other embodiments different materials can be used.

In embodiments, core portions 402a and 402b are held together by providing a pressure force in the directions indicated by the larger arrows in FIG. 4. For example, a clamp, a coupling package or piece, and/or a spring element can be used in embodiments to hold core portions 402a and 402b in their relative positions. For example, a plastic coupling piece comprising a plastic spring portion can be used, and/or a spring comprising beryllium copper (BeCu), steel, alloy or rubber or some other suitable material can be implemented. In general, the force holding core portions 402a and 402b should be sufficiently strong as to maintain the desired positional relationship and geometry of gap 408 but not so strong so as to affect the structural integrity of the soft magnetic material of core 402 or to stress package 412.

Additionally, system 400 can include a sensor package 412 comprising a fin 413 or other portion which extends at least partially into gap 408. Fin 413 can be configured in embodiments to define a width of gap 408, particularly in embodiments such as the one of system 400 in which two core portions 402a and 402b are combined to form a single core 402. Fin 413 can be integrally formed as part of package 412, thereby also functioning to maintain a spatial relationship between gap 408 and sensor elements 414a and 414b.

In embodiments, fin 413 can comprise the same material as mold compound 416 formed in other portions of package 412. For example, typical mold compound materials can comprise high silicon filler content, which has a low coefficient of thermal expansion and therefore can be beneficial for maintaining a consistent width of gap 408 when arranged therein. Other mold compound materials or configurations and compositions of fin 413 can be used in other embodiments. For example, in another embodiment fin 413 can comprise a separate portion of package 412 comprising a different filler material, a piece formed on or coupled to package 412, or one which assists in coupling package 412 to core 402 more generally.

Conductors 404, aperture 406, leads 418 and die 420 can be similar to similar elements discussed herein with respect to other figures and embodiments. Though not depicted as part of system 400, other embodiments can comprise a PCB coupled to package 412 as well as other elements and features, including those discussed with respect to other figures and embodiments herein. As previously mentioned, elements from one embodiment discussed and/or depicted herein can be used in combination with elements from other embodiments, even though specific combinations may not be discussed or depicted here.

In embodiments, a residual current sensing system, such as system 100, system 200, system 300 and/or system 400 comprises at least one test conductor such that a system self-test can be carried out. For example, and referring to system 400, test conductor can be arranged in aperture 406, and circuitry of and/or coupled to sensor system 400 or otherwise disposed in sensor package 412 can send a known test current through the test conductor. In an embodiment, the sensor system can issue or generate the test current itself, which can improve accuracy because the distance between sensor elements 414a and 414b and the test current is smaller when they are defined on the same die 420. The circuitry can then determine whether sensor elements 414a and 414b sensed the test current and can provide a corresponding output signal. In the embodiment of FIG. 3C, for example, a test conductor can be formed in or on PCB 310. The test signal can be applied on-demand, or it can be run periodically, such as every 100 ms in one embodiment.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112, sixth paragraph of 35 U.S.C. are not to be invoked unless the specific terms “means for” or “step for” are recited in a claim.

What is claimed is:

1. A residual current sensing system comprising:
a magnetic core comprising a gap having a width defined by opposing edges of the magnetic core such that the magnetic core is noncontiguous around a center aperture;
at least one current conductor disposed within the center aperture;
a sensor package having a first dimension greater than the width of the gap and arranged outside of and proximate to the gap such that the sensor package extends across the gap; and
first and second sensor elements arranged on a semiconductor die in the sensor package, and configured to sense a magnetic field induced in the magnetic core when current flows in the at least one current conductor,
wherein the first sensor element is aligned with a center axis of the gap and the second sensor element is spaced apart from the gap in a direction coaxial with the width of the gap, wherein the center axis of the gap is perpendicular to the width of the gap.

2. The system of claim 1, wherein the residual current sensor system comprises circuitry configured to determine a difference between a first sensor element signal and a second sensor element signal.

3. The system of claim 1, wherein the second sensor element is spaced apart from the gap as far as the die.

4. The system of claim 1, further comprising a third sensor element arranged on the semiconductor die in the sensor package on an opposing side of the first sensor element as compared with the second sensor element.

5. The system of claim 1, wherein the second and third sensor elements are equidistantly spaced from the first sensor element.

6. The system of claim 1, wherein the center aperture is defined by a first surface of the magnetic core, and wherein the sensor package is coupled to a second surface of the magnetic core.

7. The system of claim 1, wherein the first and second sensor elements are configured to be used as a gradiometer to sense a spatial gradient of a magnetic field.

8. The system of claim 1, wherein the residual current sensor system further comprises circuitry configured to select at least one of the first and second sensor elements to store information related to the at least one of the first and second sensor elements selected.

9. The system of claim 1, wherein each of the first and second sensor elements comprises a Hall effect sensor element, a vertical Hall effect sensor element, a giant magneto-impedance element, or a magnetoresistive sensor element.

10. The system of 1, wherein the sensor package comprises a surface mount device (SMD) package.

11. The system of claim 1, wherein the first and second sensor elements each comprise a Hall sensor element, are spaced apart from another by a distance equal to at least half a width of the gap, and are configured to be used as a differential or gradiometric sensor.

12. The system of claim 1, further comprising a test conductor disposed in the center aperture and circuitry configured to facilitate a self-test of the residual current sensing system by providing a known test current to the test conductor and determining whether the known test current is sensed by the first or second sensor element.

13. The system of claim 12, wherein the known test current is issued by a circuit disposed in the sensor package.

14. The system of claim 12, wherein the circuitry is further configured to provide an output signal that indicates whether or not the known test current is sensed.

15. The system of claim 1, wherein the at least one current conductor comprises a plurality of conductive bars arranged to be elongated in the coaxial direction and stack in a direction of the center axis of the gap.

16. The system of claim 15, wherein the plurality of conductive bars are arranged to be interleaved and coupled in series and/or parallel.

17. A method of detecting a residual current, comprising:
providing a residual current sensing system comprising a magnetic core having a gap, the gap with a width defined by opposing edges of the magnetic core such that the magnetic core is noncontiguous around a center aperture, at least one current conductor disposed within the center aperture, a sensor package having a first dimension greater than the width of the gap and arranged outside of and proximate to the gap such that the sensor package extends across the gap, and first and second sensor elements arranged on a semiconductor die in the sensor package, wherein the first sensor element is aligned with a center axis of the gap and the second sensor element is spaced apart from the gap in a direction coaxial with the width of the gap, wherein the center axis of the gap is perpendicular to the width of the gap; and
sensing, by the first and second sensor elements, a magnetic field induced in the magnetic core when current flows in at least one of a plurality of conductors disposed within the center aperture.

18. The method of claim 17, wherein each of the first and second sensor elements comprises a Hall effect sensor element, a vertical Hall effect sensor element, a giant magneto-impedance element, or a magnetoresistive sensor element.

19. The method of claim 17, further comprising:
implementing a self-test by applying a known current to a test conductor arranged in the magnetic core; and
determining whether a magnetic field induced by the known current in the magnetic core was sensed by the first or second sensor element.

20. The method of claim 19, wherein the implementing a self-test further comprises providing an output signal related to whether or not a magnetic field induced by the known current in the magnetic core was sensed by the first or second sensor element.
